(19) United States
(12) Patent Application Publication
(10) Pub. No.: US 2024/0153925 A1
(43) Pub. Date: May 9, 2024

(54) DISPLAY PANEL AND ELECTRONIC APPARATUS INCLUDING THE SAME

(71) Applicant: Samsung Display Co., LTD., Yongin-si (KR)

(72) Inventors: Jongchan LEE, Yongin-si (KR); Jinsuk LEE, Yongin-si (KR); Yongho YANG, Yongin-si (KR); Seunggyu TAE, Yongin-si (KR)

(21) Appl. No.: 18/382,200

(22) Filed: Oct. 20, 2023

(30) Foreign Application Priority Data
Nov. 9, 2022 (KR) 10-2022-0148972

(51) Int. Cl. H01L 25/075; H01L 33/44; H01L 33/52

(52) U.S. Cl. CPC H01L 25/0753; H01L 33/44; H01L 33/52

(57) ABSTRACT

A display panel includes a substrate which includes an upper surface and a lower surface and through which a through-hole that passes through the lower surface from the upper surface is defined, a light-emitting diode disposed on the upper surface of the substrate, the light-emitting diode including a first electrode, a second electrode, and an intermediate layer between the first electrode and the second electrode, and a separator disposed in an intermediate area between the light-emitting diode and the through-hole of the substrate, and including a first layer, a second layer on the first layer, and a third layer disposed below the first layer. A width of a lower surface of the second layer is greater than a width of an upper surface of the first layer, and a protective layer disposed on the separator and including a same material as a material of the first electrode of the light-emitting diode.

This application claims priority to Korean Patent Application No. 10-2022-0148972, filed on Nov. 9, 2022, and all the benefits accruing therefrom under 35 U.S.C. § 119, the content of which in its entirety is herein incorporated by reference.

### BACKGROUND

### 1. Field

Embodiments relate to a display panel and an electronic apparatus including the display panel.

### 2. Description of the Related Art

Recently, a usage of display panels is being diversified. Also, as display panels are becoming thinner and lighter in weight, their range of use is being widened.

As an area occupied by a display area in a display panel is being expanded, various functions combined or associated with a display panel are being added. As a way of adding various functions while expanding the area, research is being conducted on a use of a portion of the display area for functions other than a function of displaying images.

### SUMMARY

Embodiments include a display panel and an electronic apparatus including the display panel.

Additional features will be set forth in part in the description that follows and, in part, will be apparent from the description, or may be learned by practice of the embodiments of the disclosure.

In an embodiment of the disclosure, a display panel includes a substrate which includes an upper surface and a lower surface and through which a through-hole that passes through the lower surface from the upper surface is defined, a light-emitting diode disposed on the upper surface of the substrate, the light-emitting diode including a first electrode, a second electrode, and an intermediate layer between the first electrode and the second electrode, and a separator disposed in an intermediate area between the light-emitting diode and the through-hole of the substrate, and including a first layer, a second layer on the first layer, and a third layer disposed below the first layer, where a width of a lower surface of the second layer is greater than a width of an upper surface of the first layer, and a protective layer disposed on the separator and including a same material as that of the first electrode of the light-emitting diode.

In an embodiment, a functional layer included in the intermediate layer may extend to the intermediate area, and may include a plurality of portions separated from each other in the intermediate area, the plurality of portions of the functional layer may include a first portion overlapping the separator and the protective layer, and a second portion separated from the first portion, and a vertical distance, from the upper surface of the substrate to the first portion of the functional layer, may be greater than a vertical distance, from the upper surface of the substrate to the second portion of the functional layer.

In an embodiment, the second electrode of the light-emitting diode may extend to the intermediate area, and may include a plurality of portions disposed in the intermediate area and separated from each other, the plurality of portions of the second electrode may include a first portion overlapping the separator and the protective layer, and a second portion separated from the first portion, and a vertical distance, from the upper surface of the substrate to the first portion of the second electrode, may be greater than a vertical distance, from the upper surface of the substrate to the second portion of the second electrode.

In an embodiment, the protective layer may cover an upper surface and side surface of the second layer of the separator.

In an embodiment, the protective layer may extend to continuously cover a part of the lower surface of the second layer of the separator, a side surface of the first layer of the separator, and a part of an upper surface of the third layer of the separator.

In an embodiment, a thickness of a first portion of the protective layer disposed on the upper surface of the second layer of the separator may be greater than a thickness of a second portion of the protective layer disposed on the lower surface of the second layer of the separator.

In an embodiment, the display panel may further include an insulating layer below the separator. The protective layer is in direct contact with a part of an upper surface of the insulating layer and overlaps a side surface of the third layer of the separator.

In an embodiment, the display panel may further include an encapsulation layer disposed on the light-emitting diode, the encapsulation layer including an inorganic encapsulation layer and an organic encapsulation layer, and a partition wall disposed in the intermediate area.

In an embodiment, the separator may be disposed between the light-emitting diode and the partition wall, and the organic encapsulation layer may overlap the separator.

In an embodiment, the separator may be disposed between the partition wall and the through-hole of the substrate.

In an embodiment, the inorganic encapsulation layer may include a first inorganic encapsulation layer and a second inorganic encapsulation layer that contact each other on the separator.

In an embodiment of the disclosure, an electronic apparatus includes a display panel including a transmissive area and a display area surrounding the transmissive area, and a component which overlaps the transmissive area of the display panel. The display panel includes a substrate through which a through-hole corresponding to the transmissive area is defined, a light-emitting diode disposed on the substrate, the light-emitting diode including a first electrode, a second electrode, and an intermediate layer between the first electrode and the second electrode, a separator disposed in an intermediate area between the light-emitting diode and the through-hole of the substrate, and including a first layer, a second layer on the first layer, and a third layer disposed below the first layer, where a width of a lower surface of the second layer is greater than an upper surface of the first layer, and a protective layer disposed on the separator and including a same material as that of the first electrode of the light-emitting diode.

In an embodiment, each of a functional layer and the second electrode of the intermediate layer may extend to the intermediate area, and may include a plurality of portions disposed in the intermediate area and separated from each other, and the plurality of portions of the functional layer may include a first portion overlapping the separator and the protective layer, and a second portion separated from the first portion.

In an embodiment, the protective layer may cover an upper surface and side surface of the second layer.

In an embodiment, the protective layer may continuously cover a part of the lower surface of the second layer of the separator, a side surface of the first layer of the separator, and a part of an upper surface of the third layer of the separator.

In an embodiment, a thickness of a first portion of the protective layer disposed on the upper surface of the second layer of the separator may be greater than a thickness of a second portion of the protective layer disposed on the lower surface of the second layer of the separator.

In an embodiment, the display panel may further include an insulating layer below the separator, and the protective layer may be in direct contact with a part of an upper surface of the insulating layer and may overlap a side surface of the third layer of the separator.

In an embodiment, the display panel may include an encapsulation layer disposed on the light-emitting diode, the encapsulation layer including an inorganic encapsulation layer and an organic encapsulation layer, and a partition wall disposed in the intermediate area.

In an embodiment, the separator may be disposed between the light-emitting diode and the partition wall, and the organic encapsulation layer may overlap the separator.

In an embodiment, the separator may be disposed between the partition wall and the through-hole of the substrate, and the inorganic encapsulation layer may include a first inorganic encapsulation layer and a second inorganic encapsulation layer that contact each other on the separator.

In an embodiment, the component may include a camera or a sensor.

### BRIEF DESCRIPTION OF THE DRAWINGS

The above and other features and advantages of illustrative embodiments of the disclosure will be more apparent from the following description taken in conjunction with the accompanying drawings, in which:

FIG. 1 is a perspective view schematically illustrating an electronic apparatus;

FIG. 2 is a cross-sectional view briefly illustrating an embodiment of a display panel, and shows a cross-section taken along line II-II′ in FIG. 1;

FIG. 3 is a plan view illustrating an embodiment of a portion of a display panel;

FIG. 4 is a cross-sectional view illustrating an embodiment of a part of the display panel in FIG. 3 in an embodiment, and may correspond to a cross-sectional view taken along line III-III′ in FIG. 3;

FIG. 5 is a cross-sectional view illustrating a separator corresponding to region V in FIG. 4;

FIG. 6 is a cross-sectional view illustrating another embodiment of a portion of a display panel in another embodiment, and may correspond to a cross-sectional view taken along line III-III′ in FIG. 3;

FIG. 7 is a cross-sectional view illustrating a separator corresponding to region VI in FIG. 6;

FIGS. 8, 9, and 10A to 10C are cross-sectional views schematically illustrating an embodiment of a process of forming a separator during a manufacturing process for a display panel; and

FIGS. 11A to 11C is a cross-sectional views schematically illustrating an embodiment of a process of forming a separator during a manufacturing process for a display panel.

### DETAILED DESCRIPTION

Reference will now be made in detail to embodiments, embodiments of which are illustrated in the accompanying drawings, where like reference numerals refer to like elements throughout. In this regard, the illustrated embodiments may have different forms and should not be construed as being limited to the descriptions set forth herein. Accordingly, the embodiments are merely described below, by referring to the drawing figures, to explain features of the description. As used herein, the term “and/or” includes any and all combinations of one or more of the associated listed items. Throughout the disclosure, the expression “at least one of a, b, or c” or “at least one selected from a, b and c” indicates only a, only b, only c, both a and b, both a and c, both b and c, all of a, b, and c, or variations thereof.

The disclosure may include various embodiments and modifications, and illustrative embodiments thereof are illustrated in the drawings and will be described herein in detail. The effects and features of the disclosure and the accomplishing methods thereof will become apparent from the embodiments described below in detail with reference to the accompanying drawings. However, the disclosure is not limited to the embodiments described below and may be embodied in various modes.

Reference will now be made in detail to embodiments, illustrative embodiments of which are illustrated in the accompanying drawings, and in the drawings, the same elements are denoted by the same reference characters and a repeated explanation will be omitted.

It will be understood that although terms, such as “first” and “second,” may be used herein to describe various elements, these elements should not be limited by these terms and these terms are only used to distinguish one element from another element.

As used herein, the singular forms “a,” “an,” and “the” are intended to include the plural forms as well, unless the context clearly indicates otherwise.

Also, it will be understood that the terms “comprise,” “include,” and “have” used herein specify the presence of stated features or elements, but do not preclude the presence or addition of one or more other features or elements.

It will be understood that when a layer, region, or element is referred to as being “on” another layer, region, or element, it may be “directly on” the other layer, region, or element or may be “indirectly on” the other layer, region, or element with one or more intervening layers, regions, or elements therebetween.

Sizes of components in the drawings may be exaggerated or reduced for convenience of description. In other words, since sizes and thicknesses of elements in the drawings are arbitrarily illustrated for convenience of explanation, the following disclosure is not limited thereto.

When an illustrative embodiment may be implemented differently, a specific process order may be performed differently from the described order. For example, two processes described in succession may be performed substantially simultaneously, or may be performed in an order opposite to the described order.

In the disclosure, “A and/or B” means A or B, or A and B.

It will be understood that when a layer, region, or element is referred to as being “connected to” another layer, region, or element, it may be “directly connected to” the other layer, region, or element or may be “indirectly connected to” the other layer, region, or element with one or more intervening layers, regions, or elements therebetween. For example, when a layer, region, or element is referred to as being “electrically connected to” another layer, region, or element, it may be “directly electrically connected to” the other layer, region, or element or may be “indirectly electrically connected to” the other layer, region, or element with one or more intervening layers, regions, or elements therebetween.

The x-axis, the y-axis, and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

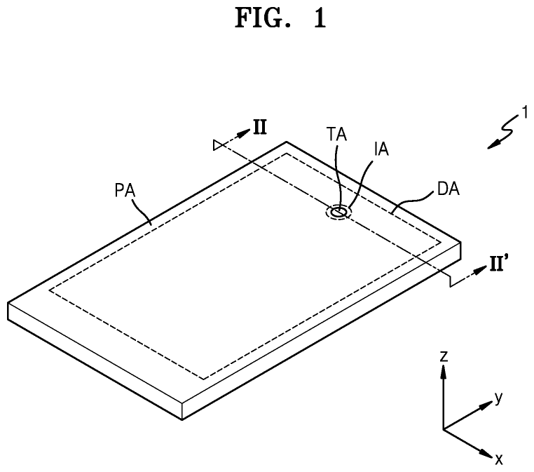

FIG. 1 is a perspective view schematically illustrating an embodiment of an electronic apparatus 1.

Referring to FIG. 1, the electronic apparatus 1 is a device for displaying a moving image or a still image and may be used as a display screen of various products, such as televisions, notebook computers, monitors, billboards, and Internet of Things (“IoT”), as well as portable electronic apparatuses, such as mobile phones, smart phones, tablet personal computers, mobile communication terminals, electronic notebooks, electronic books, portable multimedia players (“PMPs”), navigation, and Ultra Mobile PCs (“UMPCs”). In addition, the electronic apparatus 1 in an embodiment may be used in wearable devices, such as smart watches, watch phones, glasses-type displays, and head-mounted displays (“HMDs”). Furthermore, the electronic apparatus 1 in an embodiment may be used as an instrument panel of a vehicle, a center information display (“CID”) disposed on a center fascia or a dashboard of a vehicle, a room mirror display replacing a side-view mirror of a vehicle, or a display disposed on the rear side of a front seat of a vehicle as an entertainment for a rear seat of a vehicle. The electronic apparatus 1 described above may be bendable, foldable, or rollable. For convenience of explanation, FIG. 1 shows that the electronic apparatus 1 in an embodiment is used as a smartphone.

In a plan view, the electronic apparatus 1 may be formed in a quadrangular (e.g., rectangular) shape. In an embodiment, the electronic apparatus 1 may have a quadrangular (e.g., rectangular) planar shape having a short side in the x direction and a long side in the y direction, as illustrated in FIG. 1, for example. An edge where the short side in the x direction and the long side in the y direction meet each other may be formed in a round shape having a curvature or may be formed in a right-angle shape. The planar shape of the electronic apparatus 1 is not limited to a quadrangular (e.g., rectangular) shape and may be any other polygonal shape, an elliptical shape, or an irregular shape.

The electronic apparatus 1 may include a transmissive area TA (or a first area) and a display area DA (or a second area) at least partially surrounding the transmissive area TA. The electronic apparatus 1 may include an intermediate area IA disposed between the transmissive area TA and the display area DA, and a peripheral area PA surrounding the outside of the display area DA. Each of the intermediate area IA and the peripheral area PA may correspond to a non-display area, in which light is not emitted.

The transmissive area TA may be disposed within the display area DA. In an embodiment, the transmissive area TA may be disposed in the upper center of the display area DA, as shown in FIG. 1. In an alternative embodiment, the transmissive area TA may be disposed in various locations, such as being disposed at the center of the display area DA, disposed at the upper left side of the display area DA, or disposed at the upper right side of the display area DA. In a plan view of the disclosure, “left,” “right,” “up,” and “low” may refer to the directions when the electronic apparatus 1 is viewed in the vertical direction. In an embodiment, “left” may refer to the −x direction, “right” may refer to the +x direction, “up” may refer to the +y direction, and “low” may refer to the −y direction. In FIG. 1, one transmissive area TA is shown, for example. However, in another embodiment, a plurality of transmissive areas TA may be provided.

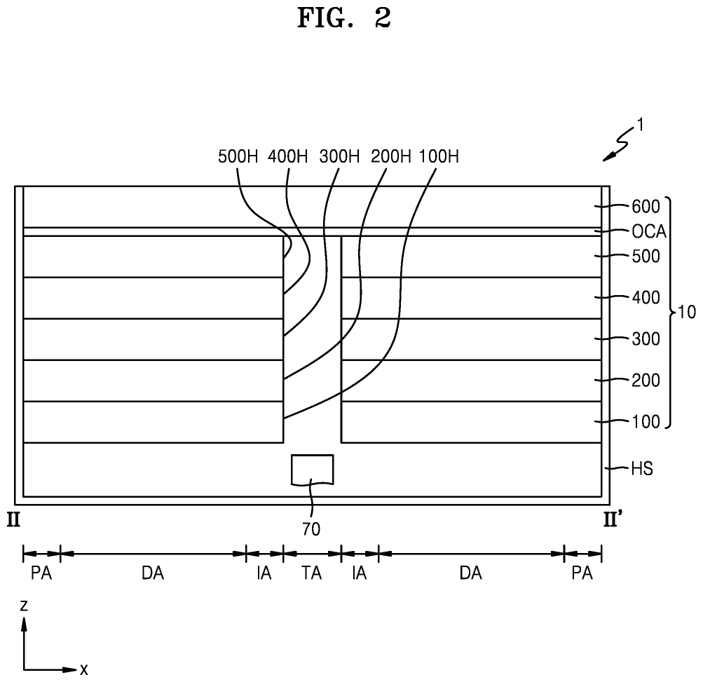

FIG. 2 is a cross-section briefly illustrating a display panel in an embodiment and shows a cross-section taken along line II-II′ in FIG. 1.

Referring to FIG. 2, the electronic apparatus 1 may include a display panel 10 and a component 70 arranged in the transmissive area TA of the display panel 10. The display panel 10 and the component 70 may be accommodated in a housing HS.

The display panel 10 may include a substrate 100, a display layer 200, an encapsulation layer 300, an input sensing layer 400, an optical functional layer 500, and a cover window 600.

The display layer 200 may include emission elements (e.g., light-emitting diodes) emitting light to display an image and circuit elements electrically connected to the light-emitting elements and comprising transistors.

The encapsulation layer 300 may seal the emission elements of the display layer 200. In an embodiment, the encapsulation layer 300 may include an inorganic encapsulation layer and an organic encapsulation layer. In another embodiment, the encapsulation layer 300 may include a sealing substrate that faces the substrate included in the display panel 10 and includes substantially the same material as the substrate.

The input sensing layer 400 may obtain coordinate information according to an external input, e.g., a touch event. The input sensing layer 400 may include a sensing electrode (or a touch electrode) and trace lines connected to the sensing electrode. The input sensing layer 400 may be disposed over the display layer 200. The input sensing layer 400 may detect an external input by a mutual capacitance method or/and a self-capacitance method.

The input sensing layer 400 may be directly formed on the display layer 200, or may be separately formed and then coupled to the display layer 200 by an adhesive layer, such as an optically clear adhesive. In an embodiment, the input sensing layer 400 may be continuously formed after a process of forming the display layer 200, and in this case, the adhesive layer may not be between the input sensing layer 400 and the display layer 200, for example. In FIG. 2, the input sensing layer 400 is disposed between the display layer 200 and the optical functional layer 500. However, in another embodiment, the input sensing layer 400 may be disposed over the optical functional layer 500.

The optical functional layer 500 may include an anti-reflection layer. The anti-reflection layer may reduce reflectivity of light (external light) that is incident toward the display panel 10 from the outside through the cover window 600. The anti-reflection layer may include a phase retarder and a polarizer.

In another embodiment, the anti-reflection layer may include a black matrix and color filters. The color filters may be arranged by taking account of a color of light emitted by each of the light-emitting diodes of the display layer 200. In another embodiment, the anti-reflection layer may include a destructive interference structure. The destructive interference structure may include a first reflective layer and a second reflective layer that are disposed in different layers from each other. First-reflected light and second-reflected light, which are respectively reflected from the first reflective layer and the second reflective layer, may destructively interfere with each other, and accordingly, reflectivity of external light may decrease.

The optical functional layer 500 may include a lens layer. The lens layer may improve emission efficiency of light emitted from the display layer 200 or reduce color deviation. The lens layer may include a layer having a lens shape that is concave or convex, or may include a plurality of layers having different refractive indices from each other. The optical functional layer 500 may include both the anti-reflection layer and the lens layer, or may include either one.

A through-hole may be defined in at least one of the substrate 100, the display layer 200, the encapsulation layer 300, the input sensing layer 400, and the optical functional layer 500. In an embodiment, FIG. 2 shows that first to fifth through-holes 100H, 200H, 300H, 400H, and 500H are defined in the substrate 100, the display layer 200, the encapsulation layer 300, the input sensing layer 400, and the optical functional layer 500, respectively. The first to fifth through-holes 100H, 200H, 300H, 400H, and 500H may overlap each other in the transmissive area TA.

The first through-hole 100H may penetrate through a lower surface of the substrate 100 from an upper surface of the substrate 100, and the second through-hole 200H may penetrate through a lower surface of the display layer 200 from an upper surface of the display layer 200. The third through-hole 300H may penetrate through a lower surface of the encapsulation layer 300 from an upper surface of the encapsulation layer 300, and the fourth through-hole 400H may penetrate through a lower surface of the input sensing layer 400 from an upper surface of the input sensing layer 400. The fifth through-hole 500H may be a through-hole that penetrates through a lower surface of the optical functional layer 500 from an upper surface of the optical functional layer 500. The first to fifth through-holes 100H, 200H, 300H, 400H, and 500H may overlap each other in the transmissive area TA. Sizes (or diameters) of the first to fifth through-holes 100H, 200H, 300H, 400H, and 500H may be equal to or different from each other.

The cover window 600 may be disposed over the optical functional layer. The cover window 600 may be coupled to the optical functional layer 500 by an adhesive layer, such as an optically clear adhesive OCA, disposed therebetween.

The cover window 600 may include a glass material or a plastic material. In an embodiment, the cover window 600 may include an ultra-thin glass window, for example. In an embodiment, the cover window 600 may include polyethersulfone, polyacrylate, polyetherimide, polyethylene naphthalate, polyethylene terephthalate, polyphenylene sulfide, polyarylate, polyimide, polycarbonate, or cellulose acetate propionate, for example.

The transmissive area TA may be a type of component area (e.g., a sensor area, a camera area, a speaker area, or the like), in which the component 70 for adding various functions to the electronic apparatus 1 is disposed. The component 70 may be disposed under the display panel 10 to overlap the first through-hole 100H of the substrate 100. In an embodiment, the component 70 may be disposed on the lower surface of the substrate 100, for example.

The component 70 may include an electronic element. In an embodiment, the component 70 may include an electronic element using light or sound, for example. In an embodiment, the electronic element may include a sensor using light, such as an infrared sensor, a camera that receives light to capture an image, a sensor that outputs and detects light or sound to measure a distance or fingerprint, a small-sized lamp outputting light, or a speaker outputting sound, for example. The electronic element that uses light may use light of various frequency bands, such as visible light, infrared light, or ultraviolet light. Light or/and sound that is output from the component 70 to the outside or progresses toward the component 70 from the outside may travel through the transmissive area TA.

In another embodiment, when the electronic apparatus 1 is used in a smartwatch or an instrumental panel for a vehicle, the component 70 may be a member including a clock needle or a needle indicating predetermined information (e.g., a vehicle speed or the like). In this case, an opening may be defined in the cover window 600 in the transmission area TA, unlike shown in FIG. 2, so as to expose the needle-like component 70 to the outside. In an alternative embodiment, even when the electronic apparatus 1 includes the component 70 that is a speaker, an opening corresponding to the transmissive area TA may be defined in the cover window 600.

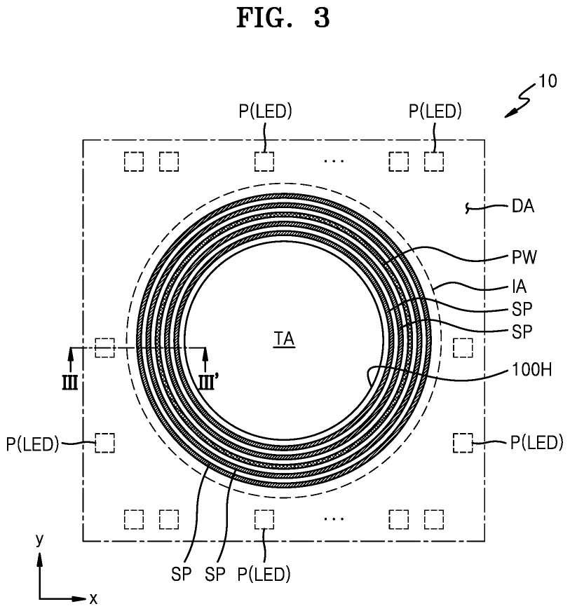

FIG. 3 is a plan view illustrating a part of an embodiment of the display panel. FIG. 3 shows the transmissive area TA of the display panel 10, the intermediate area IA surrounding the transmissive area TA, and the display area DA surrounding the intermediate area IA.

Referring to FIG. 3, sub-pixels P are arranged in the display area DA, and the intermediate area IA may be disposed between the transmissive area TA and the display area DA. The sub-pixels P may surround the transmissive area TA and the intermediate area IA in the display area DA.

The sub-pixel P, which is a smallest unit of area in which light is emitted, may emit red, green, or blue light through an emission element. The sub-pixel P may emit light by a light-emitting diode LED. A location of the sub-pixel P may correspond to a location of the light-emitting diode LED. When the sub-pixel P is disposed in the display area DA, it may indicate that the light-emitting diode LED may be disposed in the display area DA.

The sub-pixels P and/or light-emitting diodes LED adjacent to the transmissive area TA may be apart from each other with respect to the transmissive area TA, in a plan view. The sub-pixels P and/or the light-emitting diodes LEDs may be vertically or horizontally apart from each other with respect to the transmissive area TA.

In the intermediate area IA, separators SP may be apart from each other. In a plan view (e.g., when viewed from a direction perpendicular to the upper surface of the substrate 100), each of the separators SP may have a closed-loop shape. In some embodiments, the separators SP may form concentric circles, as shown in FIG. 3.

A partition wall PW may be disposed in the intermediate area IA. In a plan view, the partition wall PW may have a closed-loop shape. The partition wall PW may be disposed between two neighboring separators SP.

The separator SP may be disposed between the display area DA and the partition wall PW and/or between the partition wall PW and the transmissive area TA. FIG. 3 shows that, in some embodiments, two separators SP are disposed between the display area DA and the partition wall PW and two separators SP are disposed between the partition wall PW and the transmissive area TA. However, the disclosure is not limited thereto. In another embodiment, one separator SP or three or more separators SP may be arranged between the display area DA and the partition wall PW. One separator SP or three or more separators SP may be arranged between the partition wall PW and the transmissive area TA.

Because the first through-hole 100H corresponding to the transmissive area TA is defined in the substrate 100 of the display panel 10, herein, it may be seen that the transmissive area TA refers to the first through-hole 100H. In an embodiment, when the separator SP is disposed between the partition wall PW and the transmissive area TA, it may indicate that the separator SP is disposed between the partition wall PW and the first through-hole 100H, for example.

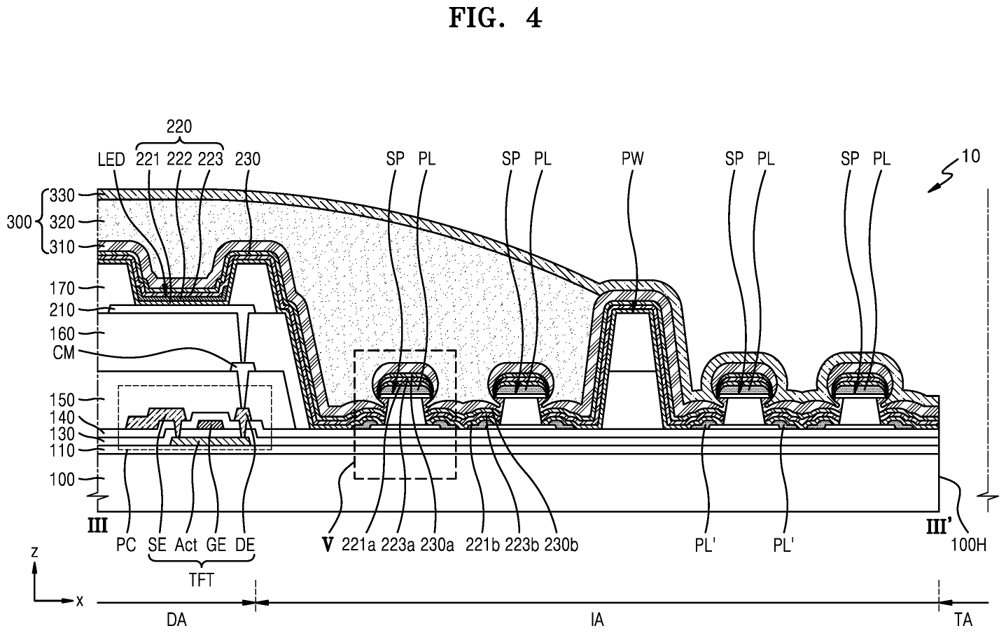

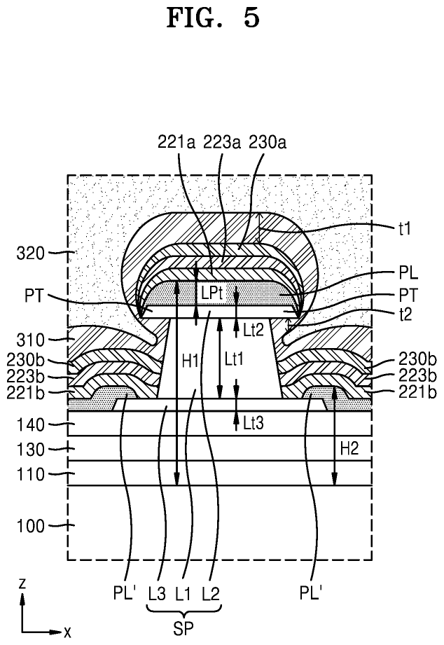

FIG. 4 is a cross-sectional view illustrating an embodiment of a part of the display panel, and may correspond to a cross-section taken along line III-III′ in FIG. 3. FIG. 5 is a cross-sectional view illustrating a separator corresponding to region V in FIG. 4. In FIG. 5, a structure of the separator SP between the display area DA and the partition wall PW is shown. However, the separator SP between the partition wall PW and the transmissive area TA may have the same structure.

Referring to FIG. 4, the display panel 10 may include the display area DA, the transmissive area TA, and the intermediate area IA therebetween. The first through-hole 100H may be defined in the substrate 100 of the display panel 10 in the transmissive area TA, and the first through-hole 100H may pass through the lower surface of the substrate 100 from the upper surface of the substrate 100.

Referring to the display area DA of FIG. 4, a sub-pixel circuit PC is disposed over the substrate 100, and the light-emitting diode LED may be disposed over the sub-pixel circuit PC.

The substrate 100 may include a glass material or polymer resin. In an embodiment, the polymer resin may include polyethersulfone, polyacrylate, polyetherimide, polyethylene naphthalate, polyethylene terephthalate, polyphenylene sulfide, polyarylate, polyimide, polycarbonate, or cellulose acetate propionate. The substrate 100 including polymer resin may be flexible, rollable, or bendable, for example. The substrate 100 may have a multi-layer structure including a layer, which includes the polymer resin described above, and an inorganic layer (not shown).

A buffer layer 110 may be disposed on the upper surface of the substrate 100. The buffer layer 110 may prevent impurities from permeating into a semiconductor layer of a transistor. The buffer layer 110 may include an inorganic insulating material, such as silicon nitride, silicon oxynitride, or silicon oxide, and may be a layer or layers including the inorganic insulating materials described above.

The sub-pixel circuit PC may be disposed on the buffer layer 110. The sub-pixel circuit PC may include a plurality of transistors and a storage capacitor, and regarding this, FIG. 4 shows a transistor TFT.

The transistor TFT may include a semiconductor layer Act on the buffer layer 110 and a gate electrode GE overlapping a channel region of the semiconductor layer Act. The semiconductor layer Act may include a silicon-based semiconductor material, e.g., polysilicon. The semiconductor layer Act may include the channel region and impurity regions at opposite sides of the channel region. One of the impurity regions at opposite ends of the channel region may correspond to a source region, and the other one may correspond to a drain region.

A first gate insulating layer 130 may be disposed between the semiconductor layer Act and the gate electrode GE. The first gate insulating layer 130 may include an inorganic insulating material, such as a silicon oxide, a silicon nitride, or a silicon oxynitride, and may include a single-layer or multi-layer structure including the inorganic insulating material described above.

The gate electrode GE may include a conductive material, including molybdenum (Mo), aluminum (Al), copper (Cu), or titanium (Ti), and may include a single-layer or multi-layer structure including the material described above.

A first inter-insulating layer 140 may be disposed on the gate electrode GE. The first inter-insulating layer 140 may include an inorganic insulating material, such as a silicon oxide, a silicon nitride, or a silicon oxynitride, and may include a single-layer or multi-layer structure including the inorganic insulating material described above.

A source electrode SE and/or a drain electrode DE may be disposed on the first inter-insulating layer 140. The source electrode SE and/or the drain electrode DE may include Al, Cu, and/or Ti, and may include a single-layer or multi-layer structure including the material(s) described above.

A second inter-insulating layer 150 may be disposed on the transistor TFT. In an embodiment, the second inter-insulating layer 150 may be disposed on the source electrode SE and/or the drain electrode DE, for example. The second inter-insulating layer 150 may include an inorganic insulating material and/or an organic insulating material. The organic insulating material may include benzocyclobutene (“BCB”), polyimide, or hexamethyldisiloxane (“HMDSO”).

A connection metal layer CM may be disposed on the second inter-insulating layer 150. The connection metal layer CM may include Al, Cu, and/or Ti, and may include a single-layer or multi-layer structure including the material(s) described above.

An organic insulating layer 160 may be disposed on the connection metal layer CM. In an embodiment, the organic insulating layer 160 may include an organic insulating material, such as BCB, polyimide, or HMDSO, for example.

The light-emitting diode LED may include a first electrode 210, an intermediate layer 220 on the first electrode 210, and a second electrode 230 on the intermediate layer 220. The first electrode 210 may be disposed on the organic insulating layer 160. In FIG. 4, the first electrode 210 is electrically connected to the connection metal layer CM through a contact hole of the organic insulating layer 160, and the connection metal layer CM is electrically connected to the sub-pixel circuit PC. However, the disclosure is not limited thereto. In another embodiment, the connection metal layer CM may be omitted, and in this case, the first electrode 210 may be electrically connected to the sub-pixel circuit PC through the contact hole of the organic insulating layer 160.

The first electrode 210 may include a reflective layer including silver (Ag), magnesium (Mg), Al, platinum (Pt), palladium (Pd), gold (Au), nickel (Ni), neodymium (Nd), iridium (Ir), chrome (Cr), or any compounds or mixtures thereof. In another embodiment, the first electrode 210 may further include a conductive oxide layer over and/or below the reflective layer described above. The conductive oxide layer may include indium tin oxide (“ITO”), indium zinc oxide (“IZO”), zinc oxide (ZnO), indium oxide (In₂O₃), indium gallium oxide (“IGO”), and/or aluminum zinc oxide (“AZO”). In an embodiment, the first electrode 210 may have a three-layer structure of an ITO layer, an Ag layer, and another ITO layer.

An edge of the first electrode 210 may overlap a bank layer 170. The bank layer 170 may include an emission opening that overlaps a part of the first electrode 210. The bank layer 170 may include an organic insulating material. In some embodiments, the bank layer 170 may include a light-shielding material.

The intermediate layer 220 may include an emission layer 222 overlapping the first electrode 210 through the emission opening of the bank layer 170. The emission layer 222 may include a polymer or low-molecular weight organic material emitting red, green, or blue light. In another embodiment, the emission layer 222 may include an inorganic material or quantum dots.

The intermediate layer 220 may include a first functional layer 221 and/or a second functional layer 223. The first functional layer 221 may include a hole transport layer (“HTL”) and/or a hole injection layer (“HIL”). The second functional layer 223 may include an electron transport layer (“ETL”) and/or an electron injection layer (“EIL”).

The second electrode 230 may include a conductive material having a relatively low work function. In an embodiment, the second electrode 230 may include a (semi-)transparent layer including Ag, Mg, Al, Pt, Pd, Au, Ni, Nd, Ir, Cr, lithium (Li), calcium (Ca), or any alloys thereof, for example. In an alternative embodiment, the second electrode 230 may further include a layer including ITO, IZO, ZnO, or In₂O₃, on the (semi-)transparent layer including the material described above.

An encapsulation layer 300 may be disposed over the light-emitting diode LED and seal the light-emitting diode LED. The encapsulation layer 300 may include an inorganic encapsulation layer and an organic encapsulation layer. In an embodiment, FIG. 4 shows that the encapsulation layer 300 includes first and second inorganic encapsulation layers 310 and 330 and an organic encapsulation layer 320 disposed therebetween.

The first inorganic encapsulation layer 310 and the second inorganic encapsulation layer 330 may include one or more inorganic materials from among Al₂O₃, titanium oxide, tantalum oxide, hafnium oxide, zinc oxide, silicon oxide, silicon nitride, and silicon oxynitride. The first inorganic encapsulation layer 310 and the second inorganic encapsulation layer 330 may include a layer or layers including the material(s) described above.

The organic encapsulation layer 320 may include a polymer-based material. In embodiments, the polymer-based material may include an acryl-based resin, epoxy-based resin, polyimide, and polyethylene. In an embodiment, the organic encapsulation layer 320 may include an acrylate.

Referring to the intermediate area IA of FIG. 4, each of the buffer layer 110, the first gate insulating layer 130, and the first inter-insulating layer 140 of the display area DA may extend toward the first through-hole 100H of the substrate 100. In other words, the buffer layer 110, the first gate insulating layer 130, and the first inter-insulating layer 140 may be disposed in the display area DA and the intermediate area IA. In an embodiment, an edge of each of the buffer layer 110, the first gate insulating layer 130, and the first inter-insulating layer 140 that face the transmissive area TA may be disposed on substantially the same vertical line on which an edge of the substrate 100 defining the first through-hole 100H is disposed, for example.

An edge of the second inter-insulating layer 150 and an edge of the organic insulating layer 160 may be disposed in the intermediate area IA. In an embodiment, the edge of the second inter-insulating layer 150 and the edge of the organic insulating layer 160 may be disposed between the display area DA and a separator SP that is disposed closest to the display area DA from among separators SP disposed in the intermediate area IA, for example.

The separators SP may be apart from each other between the edge of the organic insulating layer 160 and the first through-hole 100H of the substrate 100 (or, in the intermediate area IA). The separators SP may be disposed on an inorganic insulating layer between the edge of the organic insulating layer 160 and the first through-hole 100H of the substrate 100. Regarding this, FIG. 4 shows that the separators SP are disposed on the first inter-insulating layer 140.

As shown in FIG. 5, the separator SP may include a first layer L1, a second layer L2 on the first layer L1, and a third layer L3 below the first layer L1. Each of the first layer L1, the second layer L2, and the third layer L3 may include a conductive material. The first layer L1 may include a conductive material different from a conductive material included in the second layer L2 and/or the third layer L3.

In some embodiments, the first layer L1 may include a metal. In an embodiment, the first layer L1 may include at least one selected from among Cu, Al, Pt, Pd, Ag, Mg, Au, Ni, Nd, Ir, Cr, Li, Ca, and Mo, for example.

The second layer L2 and/or the third layer L3 may include a metal and/or a transparent conductive oxide. In an embodiment, the second layer L2 and/or the third layer L3 may include at least one selected from among Ti, Mo, and tungsten (W). In another embodiment, the second layer L2 and/or the third layer L3 may include a transparent conductive oxide (“TCO”), such as ITO.

A thickness Lt1 of the first layer L1 may be greater than a thickness Lt2 of the second layer L2 and/or a thickness Lt3 of the third layer L3. In an embodiment, the thickness Lt1 of the first layer L1 may be about 10 times to about 20 times the thickness Lt2 of the second layer L2, for example.

In some embodiments, the separator SP may be formed together with any of the source electrode SE, the drain electrode DE, and the connection metal layer CM, which are described with reference to FIG. 4, in the same process. When the separator SP has a three-layer structure of the first to third layers L1, L2, and L3, the source electrode SE, the drain electrode DE, or the connection metal layer CM may also have a three-layer structure.

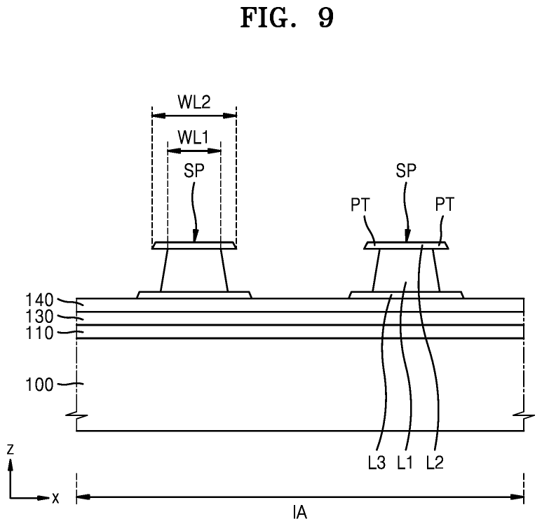

The separator SP may include a cross-sectional structure including a tip PT. In an embodiment, in the separator SP, a width WL2 (refer to FIG. 9) of a lower surface of the second layer L2 may be greater than a width WL1 (refer to FIG. 9) of an upper surface of the first layer L1. A part of the second layer L2 that protrudes in a width direction (e.g., x direction) from a point at which the upper surface and the side surface of the first layer L1 contact each other may form the tip PT, and due to the tip PT, the separator SP may have an eave structure (or an undercut structure), for example. In some embodiments, the tip PT may be disposed at opposite sides of the separator SP, respectively. Due to the eave structure of the separator SP including the tip PT, as described above, the first functional layer 221, the second functional layer 223, and/or the second electrode 230 may include portions that are separated from each other in the intermediate area IA.

A protective layer PL may be disposed on the separator SP. The protective layer PL may cover an upper and side surfaces of the second layer L2 of the separator SP, and may contact the upper and side surfaces of the second layer L2 of the separator SP.

The protective layer PL may cover the tip PT of the separator SP. In an embodiment, the protective layer PL may cover each of an upper surface and a side surface of the tip PT, for example. The protective layer PL may prevent the tip PT having a relatively small thickness from being damaged (e.g., broken). A part of the protective layer PL disposed on the side surface of the tip PT may function as eaves, similar to the tip PT, and thus, the eaves may be lengthened by the protective layer PL. A thickness LPt of the protective layer PL may be about two to three times the thickness Lt2 of the second layer L2.

The protective layer PL may include a conductive material. In an embodiment, the protective layer PL may include the same material as that of the first electrode 210 of the light-emitting diode LED, for example. In some embodiments, when the first electrode 210 of the light-emitting diode LED has a multi-layer structure, the protective layer PL may also have a multi-layer structure. In an embodiment, the number and material of sub-layers included in the first electrode 210 may be the same as the number and material of sub-layers included in the protective layer PL, for example.

In a comparative embodiment of the disclosure, when the protective layer includes an insulating material, such as an organic insulating material, the protective layer may be separated from the separator SP. However, in an embodiment of the disclosure, the protective layer PL, which is in direct contact with the separator SP, includes a conductive material, and thus, relative adhesion with the separator SP may be improved, and separation of the protective layer PL may be prevented or minimized. In addition, because the protective layer PL including the conductive material has a better moisture permeation prevention effect than a protective layer including an insulating material, the separator SP may be effectively protected.

The first functional layer 221, the second functional layer 223, and/or the second electrode 230, which are arranged in the display area DA, may include portions separated from each other by the separator SP in the intermediate area IA. In an embodiment, the first functional layer 221 and the second functional layer 223 may include first portions 221a and 223a, which are disposed on the separator SP, and second portions 221b and 223b separated from the first portions 221a and 223a. The second electrode 230 may include a first portion 230a disposed over the separator SP and a second portion 230b separated from the first portion 230a, for example.

The first portion 221a of the first functional layer 221 may be disposed on an upper surface of the protective layer PL that is on the separator SP, the first portion 223a of the second functional layer 223 may be disposed on the first portion 221a of the first functional layer 221, and the first portion 230a of the second electrode 230 may be disposed on the first portion 223a of the second functional layer 223.

The second portion 221b of the first functional layer 221, the second portion 223b of the second functional layer 223, and the second portion 230b of the second electrode 230 may respectively be disposed at levels that are different from levels at which the first portion 221a of the first functional layer 221, the first portion 223a of the second functional layer 223, and the first portion 230a of the second electrode 230 are arranged. In the disclosure, when A and B are arranged at different levels from each other, it denotes that a vertical distance from the upper surface of the substrate 100 to A and a vertical distance from the upper surface of the substrate 100 to B are different from each other.

In an embodiment, a first vertical distance H1, from the upper surface of the substrate 100 to a stack structure including the first portion 221a of the first functional layer 221, the first portion 223a of the second functional layer 223, and the first portion 230a of the second electrode 230, may be greater than a second vertical distance H2, from the upper surface of the substrate 100 to a stack structure including the second portion 221b of the first functional layer 221, the second portion 223b of the second functional layer 223, and the second portion 230b of the second electrode 230, for example.

In other words, a vertical distance from the upper surface of the substrate 100 to the first portion 221a of the first functional layer 221 may be greater than a vertical distance from the upper surface of the substrate 100 to the second portion 221b of the first functional layer 221. A vertical distance from the upper surface of the substrate 100 to the first portion 223a of the second functional layer 223 may be greater than a vertical distance from the upper surface of the substrate 100 to the second portion 223b of the second functional layer 223. In addition, a vertical distance from the upper surface of the substrate 100 to the first portion 230a of the second electrode 230 may be greater than a vertical distance from the upper surface of the substrate 100 to the second portion 230b of the second electrode 230.

Each of the second portion 221b of the first functional layer 221, the second portion 223b of the second functional layer 223, and the second portion 230b of the second electrode 230 may be disposed on an auxiliary protective layer PL′, which is described later, and the third layer L3 of the separator SP, and may be in direct contact with a side surface of the first layer L1 of the separator SP.

Because each of the first functional layer 221 and the second functional layer 223, which include an organic material, is separated from each other, moisture that may enter through the first through-hole 100H of the substrate 100 may be prevented from progressing to the light-emitting diode LED through the first functional layer 221 and the second functional layer 223.

Referring to FIG. 4, the encapsulation layer 300 may extend to the intermediate area IA. Due to a relatively excellent step coverage of the first inorganic encapsulation layer 310, the first inorganic encapsulation layer 310 may entirely and continuously overlap the separator SP. As shown in FIG. 5, the first inorganic encapsulation layer 310 may continuously extend and overlap the upper and side surfaces of the separator SP. In an embodiment, the first inorganic encapsulation layer 310 may continuously extend and overlap the upper and side surfaces of the second layer L2 of the separator SP, the side surface of the first layer L1, and the upper surface of the third layer L3, for example. The first inorganic encapsulation layer 310 may overlap the upper and side surfaces of the protective layer PL. A first thickness t1 of a part of the first inorganic encapsulation layer 310 overlapping the upper surface of the protective layer PL and/or the upper surface of the second layer L2 may be greater than a second thickness t2 of another part of the first inorganic encapsulation layer 310 covering the lower surface of the tip PT.

The auxiliary protective layer PL′ including the same material as that of the protective layer PL may be disposed on an inorganic insulating layer on which the separator SP is disposed, e.g., on the first inter-insulating layer 140. The auxiliary protective layer PL′ may be formed together with the protective layer PL in the same process. In a process of forming the protective layer PL, the auxiliary protective layer PL′ may be apart and separated from the protective layer PL according to a deposition direction of a material included in the protective layer PL, or the like. While the auxiliary protective layer PL′ contacts the upper and side surfaces of the third layer L3 of the separator SP, the auxiliary protective layer PL′ may extend onto the first inter-insulating layer 140 and contact the upper surface of an insulating layer, e.g., the first inter-insulating layer 140.

As shown in FIG. 4, a partition wall PW may be disposed in the intermediate area IA. As described above with reference to FIG. 3, the partition wall PW may have a closed-loop shape in a plan view, and the partition wall PW may control a flow of a material that is used when the organic encapsulation layer 320 is formed. An edge of the organic encapsulation layer 320 may be disposed around the partition wall PW.

Some of the separators SP may overlap the organic encapsulation layer 320. In an embodiment, the separator SP disposed between the light-emitting diode LED, which is disposed in the display area DA, and the partition wall PW may overlap the organic encapsulation layer 320, for example. The organic encapsulation layer 320 is not on the separator SP disposed between the partition wall PW and the first through-hole 100H of the substrate 100. The second inorganic encapsulation layer 330 and the first inorganic encapsulation layer 310 may contact each other on the separator SP disposed between the partition wall PW and the first through-hole 100H of the substrate 100.

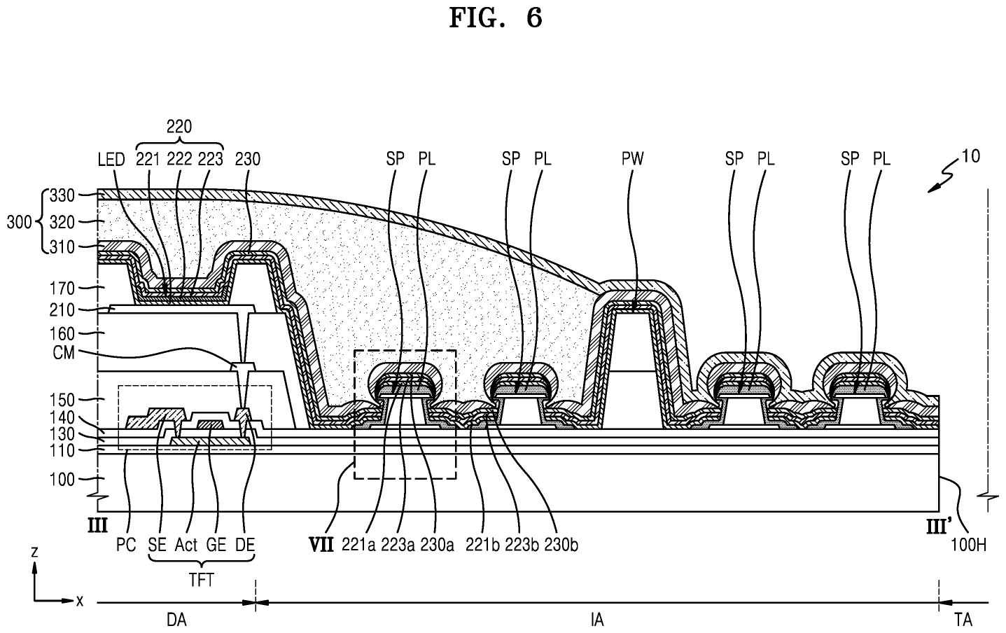

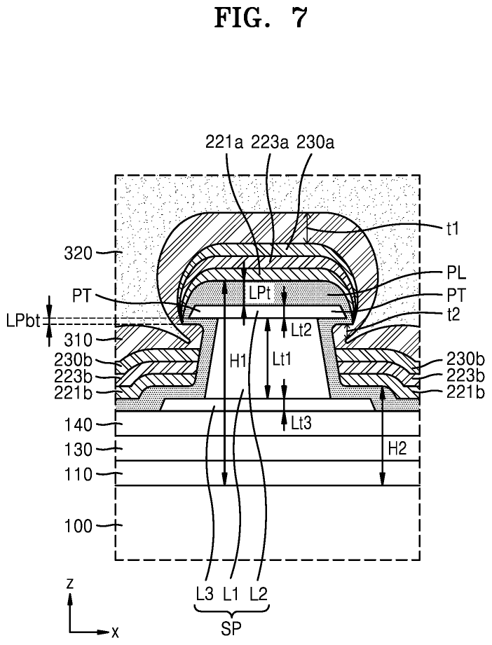

FIG. 6 is a cross-sectional view illustrating a part of a display panel in another embodiment, and may correspond to a cross-section taken along line III-III′ in FIG. 3, and FIG. 7 is a cross-sectional view illustrating a separator corresponding to region VII in FIG. 6. In FIG. 7, a structure of the separator SP between the display area DA and the partition wall PW is illustrated. However, the separator SP between the partition wall PW and the transmissive area TA may have the same structure.

Referring to the display panel 10 shown in FIG. 6, the only difference from the structure described above with reference to FIG. 4 is the shape in which the protective layer PL covers the separator SP, and other features are the same. Thus, redundant descriptions are omitted, and differences are mainly described below.

Referring to FIGS. 6 and 7, the separators SP may be apart from each other. Each of the separators SP may include the first layer L1, the second layer L2, and the third layer L3, and the structure and material of the separator SP are the same as those described with reference to FIGS. 4 and 5.

The protective layer PL may be disposed on each of the separators SP. The protective layer PL may entirely and continuously cover the upper and side surfaces of the separator SP. In an embodiment, the protective layer PL may extend to continuously cover the upper surface, side surface, and lower surface (e.g., the lower surface corresponding to a bottom surface of the tip PT) of the second layer L2 of the separator SP, the side surface of the first layer L1, and the side surface and a part of the upper surface of the third layer L3, for example.

The protective layer PL may be in direct contact with the separator SP. In an embodiment, the protective layer PL may be in direct contact with the upper surface and side surface of the second layer L2 of the separator SP, the lower surface of the second layer L2 corresponding to the tip PT, the side surface of the first layer L1, and the side surface and a part of the upper surface of the third layer L3, for example.

While the protective layer PL continuously covers the separator SP described above, the protective layer PL may extend onto the first inter-insulating layer 140 and be in direct contact with an upper surface of an insulating layer disposed under the separator SP, e.g., the first inter-insulating layer 140.

The protective layer PL may include a conductive material, e.g., the same material as a material included in the first electrode 210 of the light-emitting diode LED. When the first electrode 210 of the light-emitting diode LED has a multi-layer structure, the protective layer PL may also have a multi-layer structure.

The protective layer PL may cover the tip PT of the separator SP. In an embodiment, the protective layer PL may cover each of the upper surface, the side surface, and the lower surface of the tip PT, for example. A thickness LPt of a first portion of the protective layer PL disposed on the upper surface of the second layer L2 of the separator SP may be greater than a thickness LPbt of a second portion of the protective layer PL disposed on the lower surface (or the bottom surface of the tip PT) of the second layer L2 of the separator SP.

The protective layer PL may prevent the tip PT having a relatively small thickness from being damaged (e.g., broken). A part of the protective layer PL disposed on the side surface of the tip PT may have the same function as eaves, similar to the tip PT, and thus, the eaves may be lengthened by the protective layer PL. The thickness LPt of the first portion of the protective layer PL and a thickness Lt1, Lt2, and Lt3 of each of the first to third layers L1, L2, and L3, which correspond to the separator SP, are as described above with reference to FIG. 5.

The first portions 221a and 223a and the second portions 221b and 223b of the first functional layer 221 and the second functional layer 223, which are respectively separated from each other with respect to the separator SP, may be disposed at different levels from each other. Similarly, the first portion 230a and the second portion 230b of the second electrode 230, which are separated from each other with respect to the separator SP, may be disposed at different levels from each other. In an embodiment, a first vertical distance H1, from the upper surface of the substrate 100 to a stack structure including the first portion 221a of the first functional layer 221, the first portion 223a of the second functional layer 223, and the first portion 230a of the second electrode 230, may be greater than a second vertical distance H2, from the upper surface of the substrate 100 to a stack structure including the second portion 221b of the first functional layer 221, the second portion 223b of the second functional layer 223, and the second portion 230b of the second electrode 230, for example.

The stack structure including the first portion 221a of the first functional layer 221, the first portion 223a of the second functional layer 223, and the first portion 230a of the second electrode 230 may overlap the first to third layers L1, L2, and L3 included in the separator SP and a part of the protective layer PL.

The stack structure including the second portion 221b of the first functional layer 221, the second portion 223b of the second functional layer 223, and the second portion 230b of the second electrode 230 may be arranged at each of opposite sides with respect to the separator SP. The stack structure including the second portion 221b of the first functional layer 221, the second portion 223b of the second functional layer 223, and the second portion 230b of the second electrode 230 may overlap the first inter-insulating layer 140 and another part of the protective layer PL over the first inter-insulating layer 140.

Because the protective layer PL covers a side surface of the separator SP, e.g., a side surface of the first layer L1, each of the second portion 221b of the first functional layer 221, the second portion 223b of the second functional layer 223, and the second portion 230b of the second electrode 230 may not be in direct contact with the separator SP.

Because the first inorganic encapsulation layer 310 has a relatively excellent step coverage, the first inorganic encapsulation layer 310 may entirely and continuously overlap the separator SP, as described above.

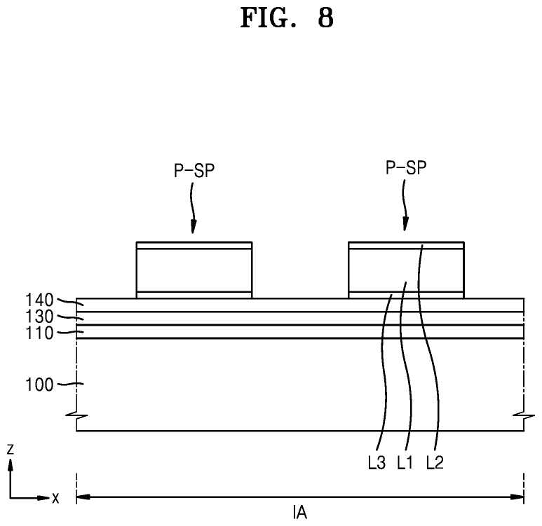

FIGS. 8, 9, and 10A to 10C are cross-sectional views schematically illustrating an embodiment of a process of forming a separator during a manufacturing process for a display panel.

Referring to FIG. 8, preliminary-separators P-SP may be formed in the intermediate area IA. Before the preliminary-separators P-SP are formed, an inorganic insulating layer, such as the buffer layer 110, the first gate insulating layer 130, or the first inter-insulating layer 140, may be formed on the substrate 100.

The preliminary-separators P-SP may be arranged apart from each other. Each of the preliminary-separators P-SP may include the first layer L1, the second layer L2 over the first layer L1, and the third layer L3 under the first layer L1.

Each of the first layer L1, the second layer L2, and the third layer L3 may include a conductive material. The first layer L1 may include a conductive material that is different from a conductive material included in the second layer L2 and/or the third layer L3.

In some embodiments, the first layer L1 may include a metal. In an embodiment, the first layer L1 may include at least one selected from among Cu, Al, Pt, Pd, Ag, Mg, Au, Ni, Nd, Ir, Cr, Li, Ca, and Mo, for example.

The second layer L2 and/or the third layer L3 may include a metal and/or a TCO. In an embodiment, the second layer L2 and/or the third layer L3 may include at least one selected from among Ti, Mo, and W. In another embodiment, the second layer L2 and/or the third layer L3 may include a TCO, such as ITO.

Next, the separator SP having an eave structure is formed as shown in FIG. 9, by etching the preliminary-separator P-SP of FIG. 8. An etching process for the preliminary-separator P-SP may be performed in the same process as an etching process for defining a contact hole of the organic insulating layer 160 included in the display area DA (refer to FIG. 4). Because the first layer L1 includes a material having an etching selectivity different from that of the second layer L2 and the third layer L3 (e.g., a conductive material having a different etching selectivity), an eave structure including the tip PT may be formed by removing a part of the first layer L1.

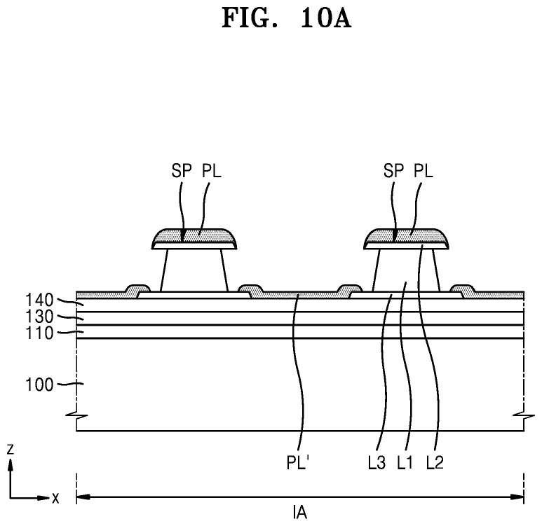

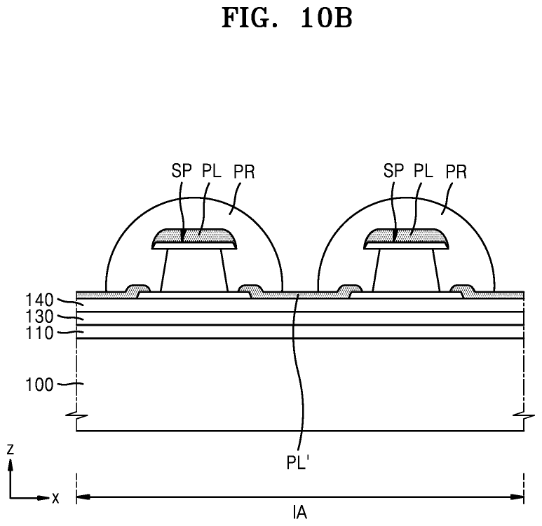

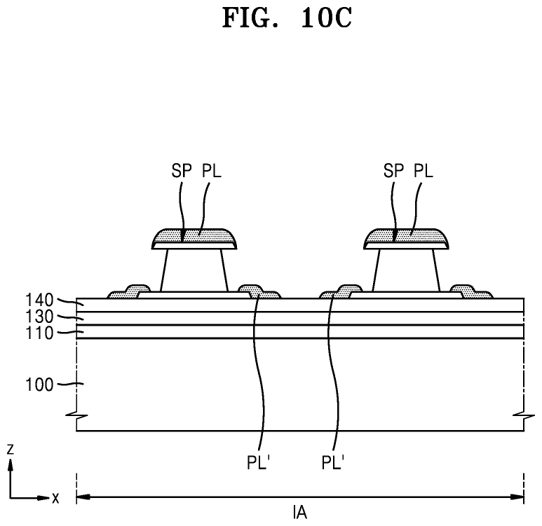

Thereafter, as shown in FIG. 10A, the protective layer PL and the auxiliary protective layer PL′ may be formed. The protective layer PL and the auxiliary protective layer PL′ may be formed together in a deposition process of a material for forming the first electrode 210 of the light-emitting diode LED disposed in the display area DA (refer to FIG. 4). The protective layer PL and the auxiliary protective layer PL′ may include the same material as that of the first electrode 210 of the light-emitting diode LED. The protective layer PL may be formed on the second layer L2 of the separator SP, and the auxiliary protective layer PL′ may be formed on the third layer L3 of the separator SP and an insulating layer (e.g., the first inter-insulating layer 140).

Next, as shown in FIG. 10B, a photoresist PR for protecting the separator SP is formed. The photoresist PR may cover the separator SP and the protective layer PL and also cover a part of the auxiliary protective layer PL′. The photoresist PR may protect the separator SP and the protective layer PL during an etching process for patterning a planar shape of the first electrode 210 of the light-emitting diode LED. The photoresist PR is removed after an etching process for forming the first electrode 210 of the light-emitting diode LED. When the photoresist PR is removed, as shown in FIG. 10C, a structure of the separator SP protected by the protective layer PL may remain in the intermediate area IA. During the etching process for forming the first electrode 210 of the light-emitting diode LED, a part of the auxiliary protective layer PL′ that is not covered by the photoresist PR may also be removed together. Accordingly, as shown in FIG. 10C, a part of the auxiliary protective layer PL′ disposed between two neighboring separators SP may be removed. In other words, it may be seen that two auxiliary protective layers PL′ that are apart from each other are disposed between the two neighboring separators SP.

In FIG. 10B, the separators SP overlap the photoresists PR, respectively, and accordingly, two auxiliary protective layers PL′ are disposed between two neighboring separators SP. However, the disclosure is not limited thereto. In another embodiment, one photoresist PR may overlap a plurality of separators SP. In this case, one auxiliary protective layer PL′ is disposed between two neighboring separators SP. In other words, the auxiliary protective layers PL′ disposed between two neighboring separators SP shown in FIG. 10C may be integrally connected to each other as a single body.

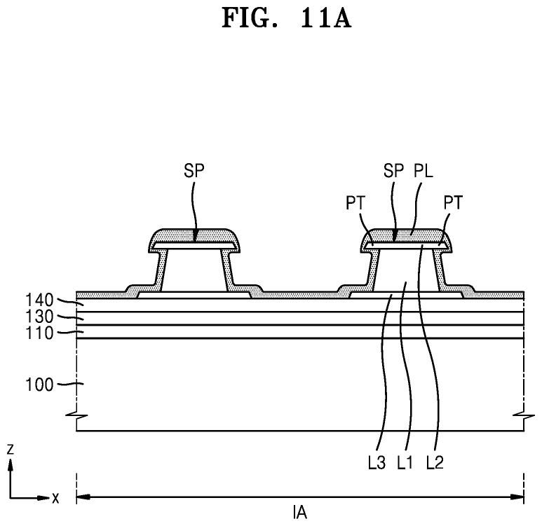

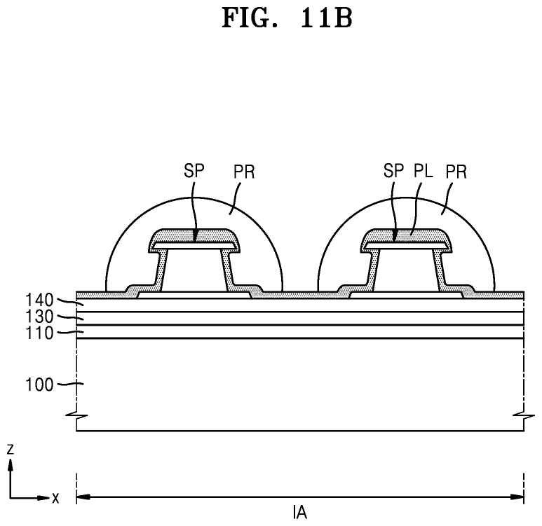

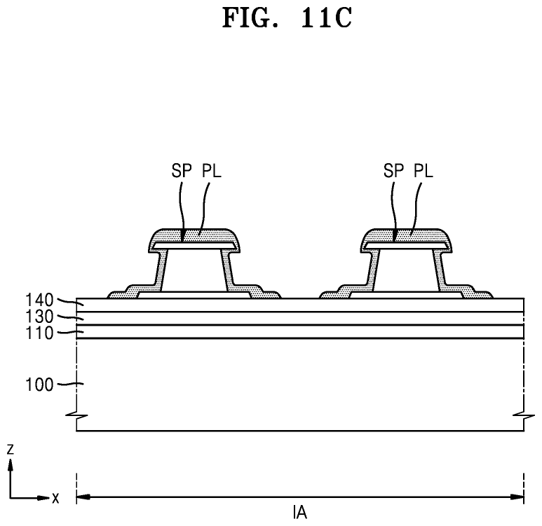

FIGS. 11A to 11C are cross-sectional views schematically illustrating an embodiment of a process of forming a separator during a manufacturing process for a display panel.

After the separator SP including the tip PT is formed in the intermediate area IA by performing the process of FIGS. 8 and 9, the protective layer PL as shown in FIG. 11A may be formed by controlling a condition of a deposition process during the process of forming the protective layer PL.

While the protective layer PL continuously covers the upper and side surfaces of the separator SP, the protective layer PL may extend onto an insulating layer disposed under the separator SP, e.g., onto the first inter-insulating layer 140. The protective layer PL may continuously cover the upper surface, side surface, and lower surface (e.g., the lower surface corresponding to the bottom surface of the tip PT) of the second layer L2 of the separator SP, the side surface of the first layer L1, and the side surface and a part of the upper surface of the third layer L3.

The protective layer PL may be in direct contact with the separator SP. In an embodiment, the protective layer PL may be in direct contact with the upper and side surfaces of the second layer L2 of the separator SP, the lower surface of the second layer L2 corresponding to the tip PT, the side surface of the first layer L1, and the side surface and a part of the upper surface of the third layer L3, for example. While the protective layer PL continuously covers the separator SP described above, the protective layer PL may extend onto the first inter-insulating layer 140 and be in direct contact with the upper surface of an insulating layer disposed under the separator SP, e.g., the first inter-insulating layer 140.

Thereafter, as shown in FIG. 11B, the photoresist PR for protecting the separator SP is formed as shown in FIG. 11B. The photoresist PR may cover the separator SP and the protective layer PL. The photoresist PR, which is for protecting the separator SP and the protective layer PL during the etching process for patterning the first electrode 210 of the light-emitting diode LED, may be removed after the etching process for forming the first electrode 210 of the light-emitting diode LED. When the photoresist PR is removed, the protective layer PL, which has a structure as shown in FIG. 11C, and the separator SP may be formed in the intermediate area IA. Because the protective layer PL and the first electrode 210 of the light-emitting diode LED include the same material as each other, a portion not protected by the photoresist PR during the etching process, e.g., a portion of the protective layer PL disposed between two neighboring separators SP, may be removed. Accordingly, as shown in FIG. 11C, a partial area of the protective layer PL disposed between the two neighboring separators SP may be removed. In other words, the protective layers PL covering the two neighboring separators SP may also be apart from each other.

In FIG. 11B, the separators SP overlap the photoresists PR, respectively, and accordingly, an area to be removed of the protective layer PL is disposed between the two neighboring separators SP. However, the disclosure is not limited thereto. In another embodiment, one photoresist PR may overlap a plurality of separators SP. In this case, one protective layer PL may continuously cover two neighboring separators SP.

When the protective layer PL covers an entirety of the upper and side surfaces of the separator SP, as shown in FIG. 11C, metal particles that may remain in the intermediate area IA during a manufacturing process for the display panel 10 (e.g., metal particles extracted from a partial area of the protective layer PL removed by not being covered by the photoresist PR) may be more effectively prevented from contaminating the separator SP and therearound.

In an embodiment, a structure of a separator having an eave structure may be protected, and because a protective layer is formed by a process of forming a light-emitting diode, the protective layer may be formed without an additional process. In addition, because the protective layer includes a conductive material, the separator may be effectively protected. These effects are only examples, and the scope of the disclosure is not limited by these effects.

It should be understood that embodiments described herein should be considered in a descriptive sense only and not for purposes of limitation. Descriptions of features or advantages within each embodiment should typically be considered as available for other similar features or advantages in other embodiments. While embodiments have been described with reference to the drawing figures, it will be understood by those of ordinary skill in the art that various changes in form and details may be made therein without departing from the spirit and scope as defined by the following claims.

What is claimed is:

1. A display panel comprising:
a substrate which comprises an upper surface and a lower surface and through which a through-hole passing through the lower surface from the upper surface is defined;
a light-emitting diode disposed on the upper surface of the substrate, the light-emitting diode comprising:
a first electrode;
a second electrode; and
an intermediate layer between the first electrode and the second electrode; and
a separator disposed in an intermediate area between the light-emitting diode and the through-hole of the substrate, and comprising:
a first layer;
a second layer on the first layer; and
a third layer disposed below the first layer, a width of a lower surface of the second layer being greater than a width of an upper surface of the first layer; and
a protective layer disposed on the separator and comprising a same material as a material of the first electrode of the light-emitting diode.

2. The display panel of claim 1, wherein a functional layer included in the intermediate layer extends to the intermediate area and comprises a plurality of portions separated from each other in the intermediate area,
the plurality of portions of the functional layer comprises:
a first portion overlapping the separator and the protective layer; and
a second portion separated from the first portion, and
a vertical distance, from the upper surface of the substrate to the first portion of the functional layer, is greater than a vertical distance, from the upper surface of the substrate to the second portion of the functional layer.

3. The display panel of claim 1, wherein the second electrode of the light-emitting diode extends to the intermediate area and comprises a plurality of portions disposed in the intermediate area and separated from each other,
the plurality of portions of the second electrode comprises:
a first portion overlapping the separator and the protective layer; and
a second portion separated from the first portion, and
a vertical distance, from the upper surface of the substrate to the first portion of the second electrode, is greater than a vertical distance, from the upper surface of the substrate to the second portion of the second electrode.

4. The display panel of claim 1, wherein the protective layer covers an upper surface and side surface of the second layer of the separator.

5. The display panel of claim 4, wherein the protective layer extends to continuously cover a part of the lower surface of the second layer of the separator, a side surface of the first layer of the separator, and a part of an upper surface of the third layer of the separator.

6. The display panel of claim 5, wherein a thickness of a first portion of the protective layer disposed on the upper surface of the second layer of the separator is greater than a thickness of a second portion of the protective layer disposed on the lower surface of the second layer of the separator.

7. The display panel of claim 5, further comprising an insulating layer below the separator,
wherein the protective layer is in direct contact with a part of an upper surface of the insulating layer and overlaps a side surface of the third layer of the separator.

8. The display panel of claim 1, further comprising:
an encapsulation layer disposed on the light-emitting diode, the encapsulation layer comprising an inorganic encapsulation layer and an organic encapsulation layer; and
a partition wall disposed in the intermediate area.

9. The display panel of claim 8, wherein the separator is disposed between the light-emitting diode and the partition wall, and the organic encapsulation layer overlaps the separator.

10. The display panel of claim 8, wherein the separator is disposed between the partition wall and the through-hole of the substrate, and
the inorganic encapsulation layer comprises a first inorganic encapsulation layer and a second inorganic encapsulation layer which contact each other on the separator.

11. An electronic apparatus comprising:
a display panel comprising:
a transmissive area;
a display area surrounding the transmissive area;
a substrate through which a through-hole corresponding to the transmissive area is defined;
a light-emitting diode disposed on the substrate, the light-emitting diode comprising:
a first electrode;
a second electrode; and
an intermediate layer between the first electrode and the second electrode;
a separator disposed in an intermediate area between the light-emitting diode and the through-hole of the substrate, and comprising:
a first layer;
a second layer on the first layer; and
a third layer disposed below the first layer, a width of a lower surface of the second layer is greater than a width of an upper surface of the first layer; and
a protective layer disposed on the separator and comprising a same material as a material of the first electrode of the light-emitting diode; and
a component which overlaps the transmissive area of the display panel.

12. The electronic apparatus of claim 11, wherein each of a functional layer and the second electrode of the intermediate layer extends to the intermediate area and comprises a plurality of portions disposed in the intermediate area and separated from each other, and
the plurality of portions of the functional layer comprise:
a first portion overlapping the separator and the protective layer; and
a second portion separated from the first portion.

13. The electronic apparatus of claim 11, wherein the protective layer covers an upper surface and side surface of the second layer.

14. The electronic apparatus of claim 13, wherein the protective layer continuously covers a part of the lower surface of the second layer of the separator, a side surface of the first layer of the separator, and a part of an upper surface of the third layer of the separator.

15. The electronic apparatus of claim 14, wherein a thickness of a first portion of the protective layer disposed on the upper surface of the second layer of the separator is greater than a thickness of a second portion of the protective layer disposed on the lower surface of the second layer of the separator.

16. The electronic apparatus of claim 14, wherein the display panel further comprises an insulating layer below the separator, and
the protective layer is in direct contact with a part of an upper surface of the insulating layer and overlaps a side surface of the third layer of the separator.

17. The electronic apparatus of claim 11, wherein the display panel comprises:
an encapsulation layer disposed on the light-emitting diode, the encapsulation layer comprising an inorganic encapsulation layer and an organic encapsulation layer; and
a partition wall disposed in the intermediate area.

18. The electronic apparatus of claim 17, wherein the separator is disposed between the light-emitting diode and the partition wall, and the organic encapsulation layer overlaps the separator.

19. The electronic apparatus of claim 18, wherein the separator is disposed between the partition wall and the through-hole of the substrate, and
the inorganic encapsulation layer comprises a first inorganic encapsulation layer and a second inorganic encapsulation layer which contact each other on the separator.

20. The electronic apparatus of claim 11, wherein the component comprises a camera or a sensor.
